(19) United States
(12) Patent Application Publication
(10) Pub. No.: US 2026/0271775 A1
(43) Pub. Date: Sep. 10, 2026

(54) SEMICONDUCTOR STRUCTURE AND MANUFACTURING METHOD THEREOF

(71) Applicant: ENKRIS SEMICONDUCTOR, INC., Suzhou, Jiangsu (CN)

(72) Inventor: Kai CHENG, Suzhou, Jiangsu (CN)

(73) Assignee: ENKRIS SEMICONDUCTOR, INC., Suzhou, Jiangsu (CN)

(21) Appl. No.: 18/724,499

(22) PCT Filed: Jun. 30, 2022
(86) PCT No.: PCT/CN2022/103179

§ 371 Date: Jun. 26, 2024

(51) Int. Cl. H10W 76/15; H10D 30/01; H10D 30/47; H10D 62/85

(52) U.S. Cl. CPC H10W 76/15; H10D 30/015; H10D 30/475; H10D 62/8503

(57) ABSTRACT

Provided are a semiconductor structure and a manufacturing method thereof. The semiconductor structure includes a base and a mask layer on the base; where the mask layer includes a window exposing the base, and the window comprises an opening end, an area for an orthographic projection of the opening end on a plane of the base is smaller than an area for an orthographic projection of the window on the plane of the base. According to embodiments of the present disclosure, a base with a mask layer is used as a substrate for epitaxially growing GaN-based materials. The opening in the mask layer has an inward sidewall in the direction from the base to the opening end. Using the inward sidewall of the window, the dislocations of the epitaxially grown GaN-based material terminate at the sidewall of the window.

### CROSS REFERENCE TO RELATED APPLICATIONS

This application is a US National Phase of PCT Application No. PCT/CN2022/103179 filed on Jun. 30, 2022, the entire content of which is incorporated herein by reference in its entirety.

### TECHNICAL FIELD

The present disclosure relates to the technical field of semiconductors, and in particular, to a semiconductor structure and a manufacturing method thereof.

### BACKGROUND

Gallium nitride (GaN) is the third generation of new semiconductor materials after the first and second generation semiconductor materials such as Si, GaAs, etc. As a wide bandgap semiconductor material, GaN has many advantages, such as high saturation drift speed and large breakdown voltage, excellent carrier transport performance and the ability to form AlGaN, InGaN ternary alloys and AlInGaN quaternary alloys, etc., which make it easy to manufacture GaN-based PN junctions. In view of this, GaN-based materials and semiconductor devices have been extensively and in-depth researched in recent years, and MOCVD (Metal-organic Chemical Vapor Deposition) technology for growing the GaN-based materials has become increasingly mature. With respect to research of semiconductor devices, research on optoelectronic devices such as LEDs (light-emitting diodes) and LDs (Laser Diodes), as well as microelectronic devices such as GaN-based HEMTs (High electron mobility transistors), has achieved remarkable results and made great progress.

With gradual deepening of the application of the GaN-based materials in power devices/display devices, the demand for dislocation density of the GaN-based materials in terminal products has further increased. According to the traditional mode, using the mainstream MOCVD epitaxial equipment, the areal density of the dislocations for the GaN-based material epitaxially grown on the mainstream GaN-based epitaxial substrate, such as an aluminum oxide (Al₂O₃) substrate, is approximately 1~3E8/cm\hat{ }3. In order to manufacture GaN-based power devices with higher voltage resistance and GaN-based LEDs with longer band, the dislocation density of the GaN-based materials must be further reduced.

In view of this, it is necessary to provide a new semiconductor structure and its manufacturing method to meet the above requirements.

### SUMMARY

The object of the present disclosure is to provide a semiconductor structure and a manufacturing method thereof to reduce the dislocation density of GaN-based materials.

In order to achieve the above object, according to a first aspect of the present disclosure, a semiconductor structure is provided, including:
a base; and
a mask layer located on the base; where the mask layer includes a window exposing the base, and the window includes an opening end, an area for an orthographic projection of the opening end on a plane of the base is smaller than an area for an orthographic projection of the window on the plane of the base.

Optionally, the window further includes a bottom wall end located on a surface of the base, and the orthographic projection of the opening end on the plane of the base is at least partially staggered from the bottom wall end.

Optionally, the orthographic projection of the opening end on the plane of the base is outside the bottom wall end.

Optionally, the window is a slanted columnar window.

Optionally, the mask layer includes a first sidewall and a second sidewall which are opposite with each other, a first angle is between the first sidewall and the base exposed by the slanted columnar window, and the first angle is an acute angle; a second angle is between the second sidewall and the base exposed by the slanted columnar window, and the second angle is an obtuse angle; and the first angle is less than or equal to a supplementary angle of the second angle.

Optionally, in a direction from the base to the opening end, areas of horizontal sections of the window first increase and then decrease; or in the direction from the base to the opening end, the areas of the horizontal sections of the window gradually decrease; or in the direction from the base to the opening end, the areas of the horizontal sections of the window are equal.

Optionally, in the direction from the base to the opening end, a line connecting centers of the horizontal sections of the window is a straight line, a broken line or a curve.

Optionally, in a direction from the base to the opening end, the window rises in a bent or twisted shape.

Optionally, the mask layer includes a plurality of windows, areas of horizontal sections of at least two of the windows are different, and/or distances between at least two pairs of adjacent windows are not equal.

Optionally, the mask layer is a multi-layer structure.

Optionally, the semiconductor structure further includes: an epitaxial layer, including a first epitaxial layer and a second epitaxial layer which are connected together; wherein the first epitaxial layer is epitaxially grown from the base until the window is filled up; and the second epitaxial layer is epitaxially grown from the first epitaxial layer located at the opening end and grown on the mask layer.

Optionally, the mask layer includes a plurality of windows, and the second epitaxial layers corresponding to the plurality of windows are coalesced into a plane.

Optionally, the second epitaxial layers first form separate structures from opening ends of the windows, and are then gradually coalesced into a plane.

Optionally, the base is a single-layer structure, and the base and the epitaxial layer are the same material or different materials; or the base includes a semiconductor substrate and a transition layer located on the semiconductor substrate, and the transition layer and the epitaxial layer are the same material or different materials.

According to the second aspect of the present disclosure, a manufacturing method of a semiconductor structure is provided, including:
providing a base; and
forming a mask layer on the base, wherein a window exposing the base is formed in the mask layer, the window includes an opening end, so that an area for an orthographic projection of the opening end on a plane of the base is smaller than an area for an orthographic projection of the window on the plane of the base.

Optionally, when forming the window, the window further includes a bottom wall end located on a surface of the base, so that the orthographic projection of the opening end on the plane of the base is at least partially staggered from the bottom wall end.

Optionally, when forming the window, the orthographic projection of the opening end on the plane of the base is outside the bottom wall end.

Optionally, when forming the window, the window is a slanted columnar window, and the slanted columnar window is formed by dry etching.

Optionally, the mask layer includes a first sidewall and a second sidewall which are opposite with each other, a first angle is between the first sidewall and the base exposed by the slanted columnar window, and the first angle is an acute angle; a second angle is between the second sidewall and the base exposed by the slanted columnar window, and the second angle is an obtuse angle; and the first angle is less than or equal to a supplementary angle of the second angle.

Optionally, the manufacturing method of the semiconductor structure further includes: using the mask layer as a mask, forming an epitaxial layer by performing an epitaxy growth process on the base, wherein the epitaxial layer includes a first epitaxial layer and a second epitaxial layer which are connected together; the first epitaxial layer is epitaxially grown from the base until the window is filled up; and the second epitaxial layer is epitaxially grown from the first epitaxial layer located at the opening end and grown on the mask layer.

Optionally, the mask layer includes a plurality of windows, and second epitaxial layers corresponding to the plurality of windows are coalesced into a plane.

Optionally, the base is a single-layer structure, and the epitaxial layer is grown by performing a homoepitaxial growth process or a heteroepitaxial growth process on the base; or the base includes a semiconductor substrate and a transition layer located on the semiconductor substrate, and the epitaxial layer is formed by performing a homoepitaxial growth process or a heteroepitaxial growth process on the transition layer.

### BRIEF DESCRIPTION OF DRAWINGS

FIG. 1 is a schematic diagram of a cross-sectional structure for a semiconductor structure according to the first embodiment of the present disclosure.

FIG. 2 is a flowchart of a manufacturing method of the semiconductor structure in FIG. 1.

FIG. 3 is a schematic diagram of an intermediate structure corresponding to a process in FIG. 2.

FIG. 4 is a schematic diagram of a cross-sectional structure for a semiconductor structure according to the second embodiment of the present disclosure.

FIG. 5 is a flowchart of a manufacturing method of a semiconductor structure according to a second embodiment of the present disclosure.

FIGS. 6(a) and 6(b) are schematic diagrams of cross-sectional structures for two semiconductor structures according to the third embodiment of the present disclosure.

FIG. 7 is a schematic diagram of a cross-sectional structure for a semiconductor structure according to the fourth embodiment of the present disclosure.

FIG. 8 is a schematic diagram of a cross-sectional structure for a semiconductor structure according to the fifth embodiment of the present disclosure.

FIG. 9 is a schematic diagram of a cross-sectional structure for a semiconductor structure according to the sixth embodiment of the present disclosure.

FIG. 10 is a schematic diagram of a cross-sectional structure for a semiconductor structure according to the seventh embodiment of the present disclosure.

FIGS. 11(a) and 11(b) are schematic diagrams of cross-sectional structures for two semiconductor structures according to the eighth embodiment of the present disclosure.

FIG. 12 is a schematic diagram of a cross-sectional structure for a semiconductor structure according to the ninth embodiment of the present disclosure.

For the convenience of understanding the present disclosure, all reference numerals appearing in the present disclosure are listed below.

| | |
|---|---|
| Semiconductor structure 1, 2, 3, 4, 5, 6,7, 8, 9 | Base 10 |
| Semiconductor substrate 100 | Transition layer 101 |
| Mask layer 11 | Window 110 |
| Opening end 110a | Bottom wall end 110b |
| Slanted columnar window 111 | First sidewall 11a |
| Second sidewall 11b | First angle α |
| Second angle β | Epitaxial layer 12 |
| First epitaxial layer 121 | Second epitaxial layer 122 |

### DETAILED DESCRIPTION

In order to make the above-mentioned objects, features and advantages of the present disclosure more obvious and understandable, embodiments of the present disclosure will be described in detail below with reference to the accompanying drawings.

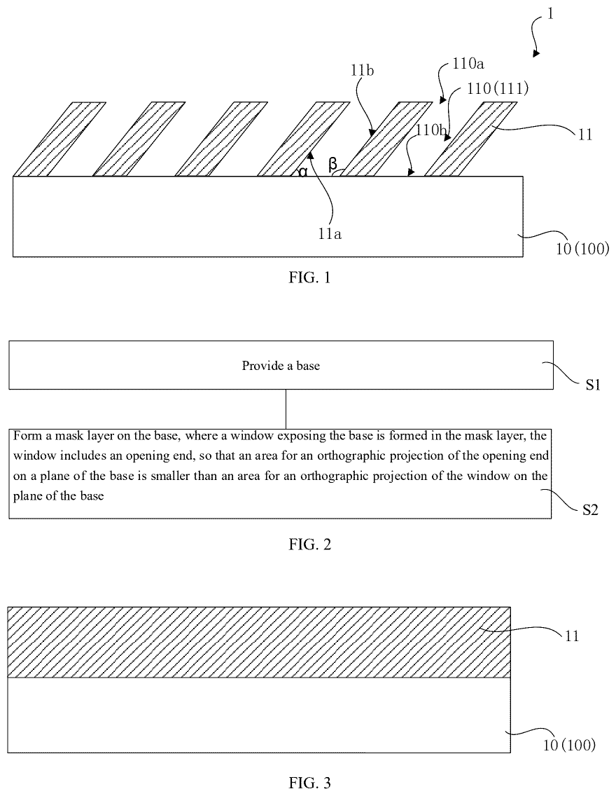

FIG. 1 is a schematic diagram of a cross-sectional structure for a semiconductor structure according to the first embodiment of the present disclosure.

Referring to FIG. 1, the semiconductor structure 1 includes:
a base 10; and
a mask layer 11 located on the base 10; where the mask layer 11 includes a window 110 that exposes the base 10, where the window 110 includes an opening end 110a, and an area for the orthographic projection of the opening end 110a on a plane of the base 10 is smaller than an area for an orthographic projection of the window 110 on the plane of the base 10.

In this embodiment, the base 10 is a multi-layer structure. The base 10 includes, for example, a semiconductor substrate 100 and a nucleation layer (not shown) located on the semiconductor substrate 100. The semiconductor substrate 100 may be made of at least one of sapphire, silicon carbide or single crystal silicon, and the nucleation layer may be made of AlN.

In other embodiments, the base 10 may be a single-layer structure, for example, the base 10 is a semiconductor substrate 100. The semiconductor substrate 100 may be made of silicon carbide, gallium nitride, etc.

The mask layer 11 may be made of at least one of silicon dioxide or silicon nitride. In this embodiment, the mask layer 11 is a single-layer structure. In other embodiments, the mask layer 11 may be a multi-layer structure, including at least two different material layers.

In this embodiment, the mask layer 11 includes a plurality of windows 110, and each window 110 is a slanted columnar window 111. A vertical section of the slanted columnar window 111 is a slanted parallelogram. The vertical section here refers to the section perpendicular to the plane of the base 10. The horizontal section of the slanted columnar window 111 is a rectangular, and the horizontal section here refers to the section parallel to the plane of the base 10. The areas of the horizontal sections of the slanted columnar windows 111 are equal, and the distances between adjacent slanted columnar windows 111 are equal.

The mask layer 11 includes a first sidewall 11a and a second sidewall 11b which are opposite with each other. A first angle α is between the first sidewall 11a and the base 10 exposed by the slanted columnar window 111. The first angle α is an acute angle. The second angle β is between the second sidewall 11b and the base 10 exposed by the slanted columnar window 111. The second angle β is an obtuse angle. The first angle α is equal to a supplementary angle of the second angle β.

The slanted columnar window 111 further includes a bottom wall end 110b located on the surface of the base 10. The orthographic projection of the opening end 110a on the plane of the base 10 is outside the bottom wall end 110b. The advantage is that: when the dislocation of the material epitaxially grown in the slanted columnar window 111 is along the thickness direction of the mask layer 11 or has an angle with the thickness direction, the smaller the angle between the sidewall of the slanted columnar window 111 and the direction of the plane of the base 10, the larger the area of the sidewall used for terminating the extension of the dislocation, thereby achieving a better termination effect. For example, when the epitaxially grown material is GaN, the dislocations of the GaN material are mainly linear dislocations in the crystal direction, that is, the linear dislocations extending along the thickness direction of the mask layer 11. At this time, the smaller the first angle α between the first sidewall 11a and the base 10 exposed by the slanted columnar window 111, the larger the area of the first sidewall 11a used for terminating the extension of the dislocation, thereby achieving a better termination effect.

In other embodiments, the orthographic projection of the opening end 110a on the plane of the base 10 and the bottom wall end 110b may be at least partially staggered.

In other embodiments, there may be one window 110, and the horizontal section of the window 110 may be a triangle, a hexagon, a circle, or other shapes.

In this embodiment, the semiconductor structure 1 is a new epitaxial substrate structure.

According to the first embodiment of the present disclosure, a manufacturing method of the semiconductor structure in FIG. 1 is provided. FIG. 2 is a flowchart of a manufacturing method; and FIG. 3 is a schematic diagram of an intermediate structure corresponding to a process in FIG. 2.

First, referring to step S1 in FIG. 2 and as shown in FIG. 3, a base 10 is provided.

In this embodiment, the base 10 is a multi-layer structure. The base 10 includes, for example, a semiconductor substrate 100 and a nucleation layer (not shown) located on the semiconductor substrate 100. The semiconductor substrate 100 may be made of at least one of sapphire, silicon carbide or single crystal silicon, and the nucleation layer may be made of AlN.

In other embodiments, the base 10 may be a single-layer structure, for example, the base 10 is a semiconductor substrate 100. The semiconductor substrate 100 may be made of silicon carbide.

Next, referring to step S2 in FIG. 2 and as shown in FIGS. 3 and 1, a mask layer 11 is formed on the base 10, and a window 110 exposing the base 10 is formed in the mask layer 11. The window 110 includes an opening end 110a, so that an area for an orthographic projection of the opening end 110a on a plane of the base 10 is smaller than an area for an orthographic projection of the window 110 on the plane of the base 10.

The mask layer 11 may be made of at least one of silicon dioxide or silicon nitride and formed using a physical vapor deposition method or a chemical vapor deposition method. In this embodiment, the mask layer 11 is a single-layer structure. The single-layer structure may be formed in one process or in multiple processes. In other embodiments, the mask layer 11 may be a multi-layer structure, including at least two different material layers which are formed in multiple processes correspondingly.

In this embodiment, when forming the window 110, there are a plurality of windows 110, and each window 110 is a slanted columnar window 111. The slanted columnar window 111 may be realized by controlling the type and the flow rate of etching gas or controlling the direction of the plasma during dry etching.

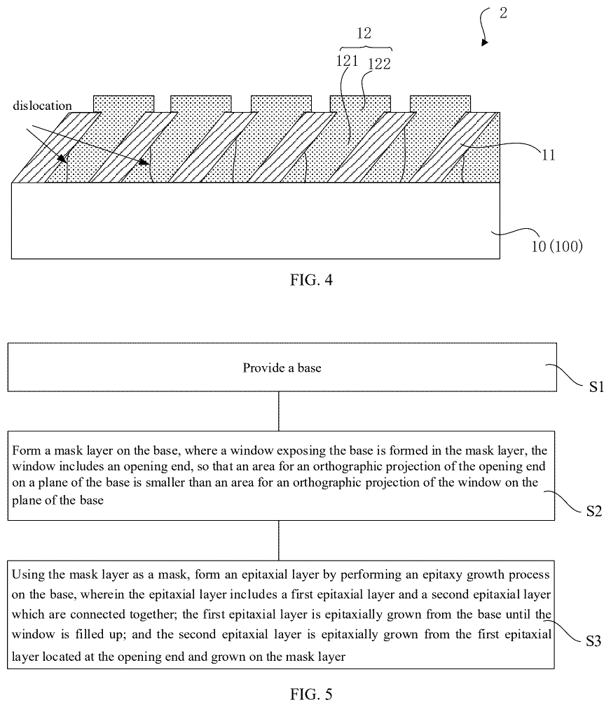

FIG. 4 is a schematic diagram of a cross-sectional structure for a semiconductor structure according to the second embodiment of the present disclosure.

Referring to FIG. 4, the difference between the semiconductor structure 2 according to the second embodiment and the semiconductor structure 1 according to the first embodiment is that: an epitaxial layer 12 is further included, and the epitaxial layer 12 includes a first epitaxial layer 121 and a second epitaxial layer 122 which are connected together. The first epitaxial layer 121 is epitaxially grown from the base 10 until the window 110 is filled up; and the second epitaxial layer 122 is epitaxially grown from the first epitaxial layer 121 located at the opening end 110a and grown on the mask layer 11.

The materials of the first epitaxial layer 121 and the second epitaxial layer 122 are the same, and may be at least one of GaN, AlGaN, InGaN, or AlInGaN, which is not limited in this embodiment.

Except for the above differences, other structures of the semiconductor structure 2 according to the second embodiment can be referred to the corresponding structure of the semiconductor structure 1 according to the first embodiment.

FIG. 5 is a flowchart of a manufacturing method of a semiconductor structure according to a second embodiment of the present disclosure. Referring to FIGS. 5 and 2, correspondingly, regarding the manufacturing method, the difference between the manufacturing method of the semiconductor structure 2 according to the second embodiment and the manufacturing method of the semiconductor structure 1 according to the first embodiment is that: step S3 is further included. In step S3, using the mask layer 11 as a mask, the epitaxial growth process is performed on the base 10 to form the epitaxial layer 12. The epitaxial layer 12 includes a first epitaxial layer 121 and a second epitaxial layer 122 which are connected together. The first epitaxial layer 121 is epitaxially grown from the base 10 until the window 110 is filled up; and the second epitaxial layer 122 is epitaxially grown from the first epitaxial layer 121 located at the opening end 110a and grown on the mask layer 11.

Forming process for the epitaxial layer 12 may include: Atomic Layer Deposition (ALD), or Chemical Vapor Deposition (CVD), or Molecular Beam Epitaxial (MBE), or Plasma Enhanced Chemical Vapor Deposition (PECVD), or Low Pressure Chemical Vapor Deposition (LPCVD), or Metal-Organic Chemical Vapor Deposition (MOCVD), or a combination thereof.

When the base 10 is a multi-layer structure, for example, the base 10 includes a semiconductor substrate 100 and a nucleation layer located on the semiconductor substrate 100, the first epitaxial layer 121 and the second epitaxial layer 122 epitaxially grown on the base 10 are heteroepitaxial layers. When the base 10 is a single-layer structure, for example, the base 10 is a silicon carbide semiconductor substrate 100, the first epitaxial layer 121 and the second epitaxial layer 122 are homoepitaxial layers.

Materials of the first epitaxial layer 121 and the second epitaxial layer 122 are the same, and may be a GaN-based material. A dislocation in the GaN-based material is along a thickness direction of the mask layer 11, or an angle is between the dislocation in the GaN-based material and the thickness direction of the mask layer 11. The area of the orthographic projection for the opening end 110a of the window on the plane of the base 10 is smaller than the area of the orthographic projection for the window 110 on the plane of the base 10, which means that, in the direction from the bottom wall end 110b toward the opening end 110a, the window 110 has an inward sidewall. The inward sidewall of the window 110 may result in the dislocations of the epitaxially grown GaN-based material are terminated at the sidewall of the window 110 and cannot continue to extend with the growth of the GaN-based material. Therefore, the base 10 having the above-mentioned mask layer 11 can reduce the dislocations of the epitaxial layer 12.

Except for the above differences, the manufacturing method of the semiconductor structure 2 according to the second embodiment can be referred to the corresponding process steps of the semiconductor structure 1 according to the first embodiment.

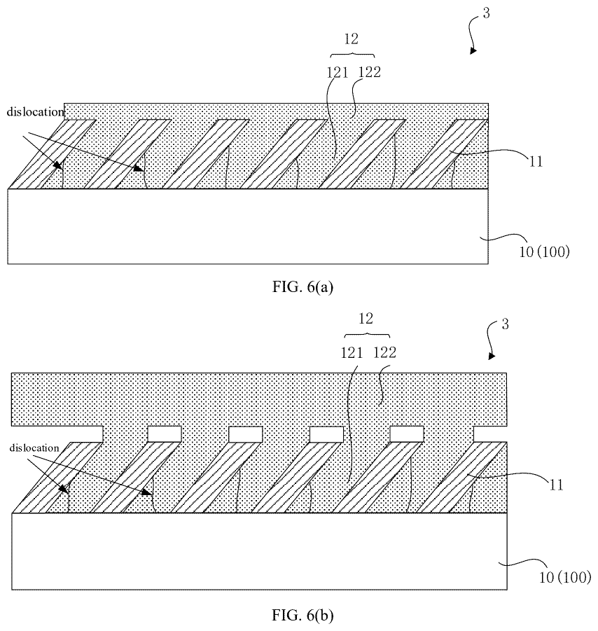

FIGS. 6(a) and 6(b) are schematic diagrams of cross-sectional structures for two semiconductor structures according to the third embodiment of the present disclosure.

Referring to FIG. 6(a) and FIG. 6(b), the difference between the semiconductor structure 3 according to the third embodiment and the semiconductor structures 1 and 2 according to the first and second embodiments is that: the second epitaxial layers 122 corresponding to the windows 110 are coalesced into a plane.

Referring to FIG. 6(a) and FIG. 6(b), the mask layer 11 may be in a mesh shape or a strip shape. The difference between FIG. 6(b) and FIG. 6(a) is that: after epitaxially growing a certain thickness on the first epitaxial layer 121, the second epitaxial layers 122 are gradually coalesced into a plane, that is, in the epitaxial growth direction, the second epitaxial layers 122 first form separate structures spaced apart from each other and is then gradually coalesced into a flat surface. There are gaps between separate structures.

GaN-based devices, such as LD, LED or HEMT devices, may be formed on the second epitaxial layer 122.

Except for the above differences, other structures of the semiconductor structure 3 according to the third embodiment can be referred to the corresponding structures of the semiconductor structures 1, 2 according to the first and second embodiments.

Correspondingly, the difference between the manufacturing method of the semiconductor structure 3 according to the third embodiment and the manufacturing methods of the semiconductor structures 1, 2 according to the first and second embodiments is that: in step S3, by increasing the process time, the second epitaxial layers 122 respectively corresponding to the windows 110 are coalesced into a plane, or by controlling epitaxial growth conditions, the second epitaxial layer 122 with gaps is obtained.

Except for the above differences, the other steps of the manufacturing method of the semiconductor structure 3 according to the third embodiment can be referred to the corresponding steps of the manufacturing method of the semiconductor structure 2 according to the second embodiment.

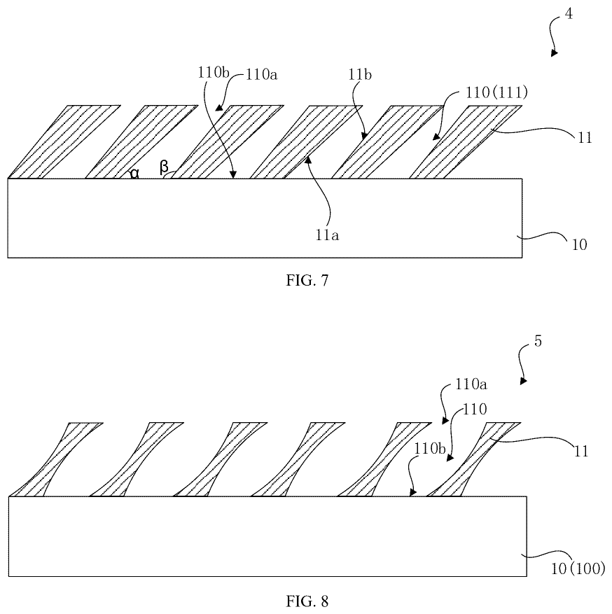

FIG. 7 is a schematic diagram of a cross-sectional structure for a semiconductor structure according to the fourth embodiment of the present disclosure.

Referring to FIG. 7, the difference between the semiconductor structure 4 and the manufacturing method thereof according to the fourth embodiment and the semiconductor structures 1, 2, 3 and the manufacturing methods thereof according to the first, second and third embodiments is that: in the slanted columnar window 111, the first angle α is smaller than the supplementary angle of the second angle β.

Decreasing the first angle α can increase the area of the first sidewall 11a that terminates dislocation extension, so the effect of terminating the dislocations in the epitaxial layer 12 is better.

Except for the above differences, other structures of the semiconductor structure 4 according to the fourth embodiment can be referred to the corresponding structures of the semiconductor structures 1, 2, 3 according to the first, second, third embodiments.

FIG. 8 is a schematic diagram of a cross-sectional structure for a semiconductor structure according to the fifth embodiment of the present disclosure.

Referring to FIG. 8, the difference between the semiconductor structure 5 and the manufacturing method thereof according to the fifth embodiment and the semiconductor structures 1, 2, 3, 4 and the manufacturing method thereof according to the first to fourth embodiments is that: in the direction from the base 10 to the opening end 110a, areas of the horizontal sections of the window 110 first increase and then decrease.

The area of the horizontal section of the window 110 refers to the area of the section parallel to the plane of the base 10.

Except for the above differences, other structures and process steps of the semiconductor structure 5 according to the fifth embodiment can be referred to the corresponding structures and process steps of the semiconductor structures 1, 2, 3, 4 according to the first to fourth embodiments.

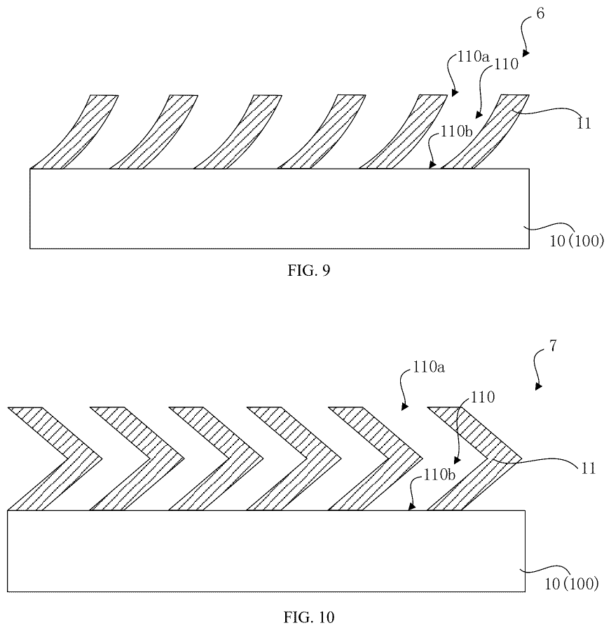

FIG. 9 is a schematic diagram of a cross-sectional structure for a semiconductor structure according to the sixth embodiment of the present disclosure.

Referring to FIG. 9, the difference between the semiconductor structure 6 and the manufacturing method thereof according to the sixth embodiment and the semiconductor structures 1, 2, 3, 4, 5 and the manufacturing method thereof according to the first to fifth embodiments is that: in the direction from the base 10 to the opening end 110a, the areas of the horizontal sections of the window 110 are the same, and a line connecting the centers of the horizontal sections of the window 110 is a curve.

In other embodiments, in the direction from the base 10 to the opening end 110a, the areas of the horizontal sections of the window 110 may first decrease and then increase or gradually decrease; and/or the horizontal section of the window 110 may be a figure with a symmetrical center, and in the direction from the base 10 to the opening end 110a, a line connecting the centers of the horizontal sections of the window 110 is a straight line.

Except for the above differences, other structures and process steps of the semiconductor structure 6 according to the sixth embodiment can be referred to the corresponding structures and process steps of the semiconductor structures 1, 2, 3, 4, 5 according to the first to fifth embodiments.

FIG. 10 is a schematic diagram of a cross-sectional structure for a semiconductor structure according to the seventh embodiment of the present disclosure.

Referring to FIG. 10, the difference between the semiconductor structure 7 and the manufacturing method thereof according to the seventh embodiment and the semiconductor structures 1, 2, 3, 4, 5, 6 and the manufacturing method thereof according to the first to sixth embodiments is that: in the direction from the base 10 to the opening end 110a, a line connecting the centers of the horizontal sections of the window is a broken line. In other words, in the direction from the base 10 to the opening end 110a, the window 110 rises in a bent shape.

In other embodiments, in the direction from the base 10 to the opening end 110a, the window 110 may rise in a twisted shape.

Except for the above differences, other structures and process steps of the semiconductor structure 7 according to the seventh embodiment can be referred to the corresponding structures and process steps of the semiconductor structures 1, 2, 3, 4, 5, 6 according to the first to sixth embodiments.

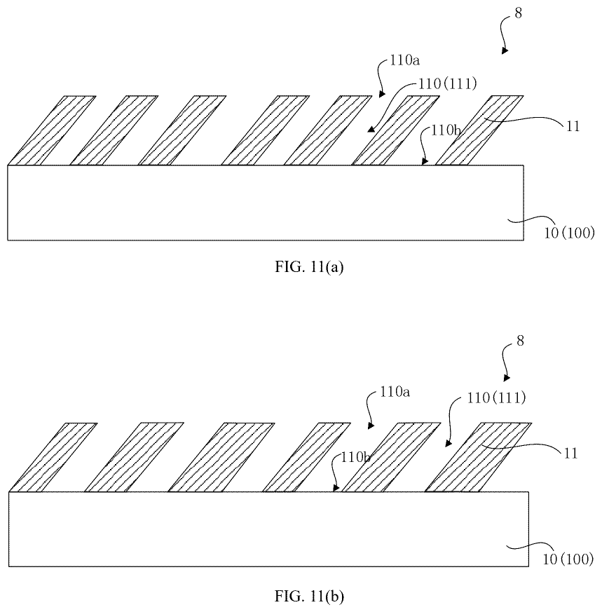

FIGS. 11(a) and 11(b) are schematic diagrams of cross-sectional structures for two semiconductor structures according to the eighth embodiment of the present disclosure.

The only difference between the semiconductor structure 8 and the manufacturing method of the eighth embodiment and the semiconductor structures 1, 2, 3, 4, 5, 6, 7 and the manufacturing method of the first to seventh embodiments is that: there are multiple windows 110, as shown in FIG. 11(a), where the areas of the horizontal sections of at least two windows 110 are not equal in size, and as shown in FIG. 11(b), the distances between at least two pairs of adjacent windows 110 are not equal.

Among the three windows 110 in each group, the areas of the horizontal sections of the windows 110 may be unequal, and the distances between two pairs of adjacent windows 110 may be unequal.

The size and the spacing of the window 110 can enrich the quality or properties of the material to be epitaxially grown.

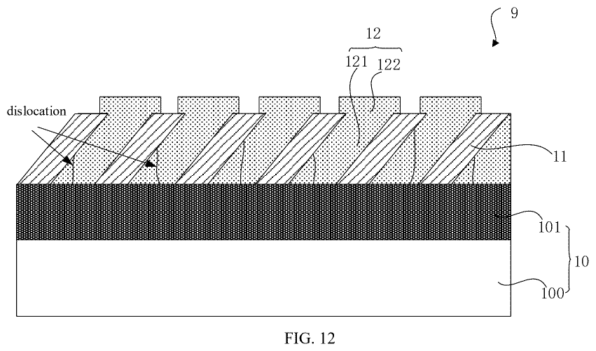

FIG. 12 is a schematic diagram of a cross-sectional structure for a semiconductor structure according to the ninth embodiment of the present disclosure.

Referring to FIG. 12, the difference between the semiconductor structure 9 and the manufacturing method of the ninth embodiment and the semiconductor structures 1, 2, 3, 4, 5, 6, 7, 8 and the manufacturing method of the first to eighth embodiments are only: the base 10 includes a semiconductor substrate 100 and a transition layer 101 located on the semiconductor substrate 100.

The transition layer 101 and the epitaxial layer 12 may be made of the same material or different materials.

The transition layer 101 is made of the material, for example, GaN. Compared with the embodiments in which the transition layer 101 is omitted and the epitaxial layer 12 made of the material, such as AlGaN, InGaN, AlInGaN, is directly epitaxially grown on the semiconductor substrate 100 made of the sapphire or single crystal silicon, this embodiment can further reduce the dislocation density in the epitaxial layer 12.

Except for the above differences, other structures and process steps of the semiconductor structure 9 according to the ninth embodiment can be referred to the corresponding structures and process steps of the semiconductor structures 1, 2, 3, 4, 5, 6, 7, 8 according to the first to eighth embodiments.

Compared with the prior art, the present disclosure has the following beneficial effects:
a base with a mask layer is used as the base for epitaxial growth of the GaN-based materials, and an area for an orthographic projection of the opening end for an opening on a plane of the base is smaller than an area for an orthographic projection of the window on the plane of the base. Using the inward sidewall of the window, the dislocations of the epitaxially grown GaN-based material terminate at the sidewall of the window and cannot continue to extend with the growth of the GaN-based material. Therefore, the base with the above mask layer can reduce the dislocation density of the GaN-based materials.

Although the present disclosure is disclosed as above, the present disclosure is not limited thereto. Any person skilled in the art may make various changes and modifications without departing from the spirit and scope of the present disclosure, and therefore the scope of protection of the present disclosure shall be subject to the scope defined by the claims.

1. A semiconductor structure, comprising:
a base; and
a mask layer located on the base; wherein the mask layer comprises a window exposing the base, and the window comprises an opening end, an area for an orthographic projection of the opening end on a plane of the base is smaller than an area for an orthographic projection of the window on the plane of the base.

2. The semiconductor structure according to claim 1,
wherein the window further comprises a bottom wall end located on a surface of the base, and the orthographic projection of the opening end on the plane of the base is at least partially staggered from the bottom wall end.

3. The semiconductor structure according to claim 2,
wherein the orthographic projection of the opening end on the plane of the base is outside the bottom wall end.

4. The semiconductor structure according to any one of claim 1, wherein the window is a slanted columnar window.

5. The semiconductor structure according to claim 4, wherein the mask layer comprises a first sidewall and a second sidewall which are opposite with each other, a first angle is between the first sidewall and the base exposed by the slanted columnar window, and the first angle is an acute angle; a second angle is between the second sidewall and the base exposed by the slanted columnar window, and the second angle is an obtuse angle; and the first angle is less than or equal to a supplementary angle of the second angle.

6. The semiconductor structure according to claim 1, wherein in a direction from the base to the opening end, areas of horizontal sections of the window first increase and then decrease; or in the direction from the base to the opening end, the areas of the horizontal sections of the window gradually decrease; or in the direction from the base to the opening end, the areas of the horizontal sections of the window are equal.

7. The semiconductor structure according to claim 1, wherein in a direction from the base to the opening end, a line connecting centers of horizontal sections of the window is a straight line, a broken line or a curve.

8. The semiconductor structure according to claim 1, wherein the mask layer comprises a plurality of windows, areas of horizontal sections of at least two of the windows are different, and/or distances between at least two pairs of adjacent windows are not equal.

9. The semiconductor structure according to claim 1, wherein the mask layer is a multi-layer structure.

10. The semiconductor structure according to claim 1, further comprising:
an epitaxial layer, comprising a first epitaxial layer and a second epitaxial layer which are connected together; wherein the first epitaxial layer is epitaxially grown from the base until the window is filled up; and the second epitaxial layer is epitaxially grown from the first epitaxial layer located at the opening end and grown on the mask layer.

11. The semiconductor structure according to claim 10, wherein the mask layer comprises a plurality of windows, and second epitaxial layers corresponding to the plurality of windows are coalesced into a plane.

12. The semiconductor structure according to claim 11, wherein the second epitaxial layers first form separate structures from opening ends of the windows, and are then gradually coalesced into a plane.

13. The semiconductor structure according to any one of claim 10, wherein the base is a single-layer structure, and the base and the epitaxial layer are the same material or different materials; or the base comprises a semiconductor substrate and a transition layer located on the semiconductor substrate, and the transition layer and the epitaxial layer are the same material or different materials.

14. A manufacturing method of a semiconductor structure, comprising:
providing a base; and
forming a mask layer on the base, wherein a window exposing the base is formed in the mask layer, the window comprises an opening end (110a), so that an area for an orthographic projection of the opening end on a plane of the base is smaller than an area for an orthographic projection of the window on the plane of the base.

15. The manufacturing method of the semiconductor structure according to claim 14, wherein when forming the window, the window further comprises a bottom wall end located on a surface of the base, so that the orthographic projection of the opening end on the plane of the base is at least partially staggered from the bottom wall end.

16. The manufacturing method of the semiconductor structure according to claim 14, wherein when forming the window, the window is a slanted columnar window, and the slanted columnar window is formed by dry etching.

17. The manufacturing method of the semiconductor structure according to claim 16, wherein the mask layer comprises a first sidewall and a second sidewall which are opposite with each other, a first angle is between the first sidewall and the base exposed by the slanted columnar window, and the first angle is an acute angle; a second angle is between the second sidewall and the base exposed by the slanted columnar window, and the second angle is an obtuse angle; and the first angle is less than or equal to a supplementary angle of the second angle.

18. The manufacturing method of the semiconductor structure according to claim 14, further comprising:
using the mask layer as a mask, forming an epitaxial layer by performing an epitaxy growth process on the base, wherein the epitaxial layer comprises a first epitaxial layer and a second epitaxial layer which are connected together; the first epitaxial layer is epitaxially grown from the base until the window is filled up; and the second epitaxial layer is epitaxially grown from the first epitaxial layer located at the opening end and grown on the mask layer.

19. The manufacturing method of the semiconductor structure according to claim 18, wherein the mask layer comprises a plurality of windows, and second epitaxial layers corresponding to the plurality of windows are coalesced into a plane.

20. The manufacturing method of the semiconductor structure according to claim 18, wherein the base is a single-layer structure, and the epitaxial layer is grown by performing a homoepitaxial growth process or a heteroepitaxial growth process on the base; or the base comprises a semiconductor substrate and a transition layer located on the semiconductor substrate, and the epitaxial layer is formed by performing a homoepitaxial growth process or a heteroepitaxial growth process on the transition layer.
